(19) United States
(12) Patent Application Publication
(10) Pub. No.: US 2022/0020923 A1
(43) Pub. Date: Jan. 20, 2022

(54) PHASE-CHANGE MATERIAL AND ASSOCIATED RESISTIVE PHASE-CHANGE MEMORY

(71) Applicant: Commissariat à l'énergie atomique et aux énergies alternatives, PARIS (FR)

(72) Inventors: Gabriele NAVARRO, GRENOBLE CEDEX 09 (FR); Marie-Claire CYRILLE, GRENOBLE CEDEX 09 (FR)

(21) Appl. No.: 17/376,828

(22) Filed: Jul. 15, 2021

(30) Foreign Application Priority Data
Jul. 15, 2020 (FR) 2007416

(51) Int. Cl. H01L 45/00; C01B 19/00

(52) U.S. Cl. CPC H01L 45/144; H01L 45/06; C01P 2002/72; C01B 19/007; C01P 2006/33; H01L 45/16

(57) ABSTRACT

A phase-change material includes germanium Ge, tellurium Te and antimony Sb, including at least 37% germanium Ge, the ratio between the quantity of antimony Sb and the quantity of tellurium Te being between 1.5 and 4.

### TECHNICAL FIELD OF THE INVENTION

The technical field of the invention is that of materials for phase-change memory and more particularly that of phase-change materials that can be used as active materials of resistive phase-change memories.

The present invention relates to a phase-change material. The present invention also relates to a resistive phase-change memory and associated methods of manufacture.

### TECHNOLOGICAL BACKGROUND OF THE INVENTION

Resistive phase-change memories or PCM memories (for “Phase-Change Memory”) are resistive memories comprising an active zone based on a chalcogenide material located between two electrodes. The operation of PCM memories is based on phase transition of the chalcogenide material, induced by the heating of this material under the effect of specific electrical pulses applied via its two electrodes. This transition is done between a crystalline phase, of low resistance and thermodynamically stable, called LRS state (for “Low-Resistive State” also referred to as “SET”) and an amorphous phase, disordered, of high resistance and thermodynamically unstable, called HRS state (for “High-Resistive State also referred to as “RESET”).

In automotive applications, PCM memories are subjected for a few minutes to temperatures of about 250° C. and for years to temperatures greater than 150° C. To preserve the information stored in PCM memories when they are manufactured and during the use thereof, the latter must not crystallise when they are subjected to such temperatures: their active material must therefore have a crystallisation temperature greater than 250° C.

However, the materials that constitute the active layer of the PCM memories, such as the material Ge₂Sb₂Te₅, are subject to the “drift” phenomenon for the LRS or SET state. This “drift” phenomenon corresponds to a change over time and under the effect of the temperature, in the electrical resistance of the crystalline phase of the material to increasingly higher values, able to approach the electrical resistance of the material in the HRS or RESET state, i.e. in amorphous phase. The two resistive states LRS and HRS of the PCM memory can then no longer be sufficiently distinct for the PCM memory to operate nominally.

There is therefore a need to provide a PCM memory that has a high crystallisation temperature, and in particular greater than 250° C., not subject to the “drift” phenomenon for the LRS or SET state.

### SUMMARY OF THE INVENTION

The invention offers a solution to the problems mentioned hereinabove, by making it possible to obtain a PCM memory that crystallises at a temperature in particular compatible with an automotive or embedded application, i.e. greater than 250° C., with a LRS or SET state having a resistance that changes little over time.

A first aspect of the invention relates to a phase-change material comprising germanium Ge, tellurium Te and antimony Sb, comprising at least 37% germanium Ge, the ratio between the quantity of antimony Sb and the quantity of tellurium Te being comprised between 1.5 and 4.

Thanks to the invention, under the effect of a strong electrical pulse, in particular at the initialisation step, also referred to as the forming step, the material will reorganise itself to create a first zone and a second zone having different compositions. Indeed, during the initialisation, a portion of the germanium Ge located in the first zone Z1 is expelled towards the second zone Z2, in such a way as to deplete the first zone Z1 of germanium Ge, the Sb/Te ratio remaining substantially identical in the first zone Z1 and the second zone Z2. After initialisation, the first zone Z1 comprises a material called Delta material, constituted of 10.7% germanium Ge, 62.7% antimony Sb and 26.6% tellurium Te and germanium Ge in excess. As the Delta material has a trigonal phase, even hexagonal phase, it has a crystalline growth that is faster than a conventional ternary mixture, such as Ge₂Sb₂Te₅, which crystallises in the cubic phase and generates a very substantial “drift” phenomenon on the SET state, and therefore is itself not subject to the “drift” phenomenon for the LRS or SET state. In addition, the Delta material has a crystallisation temperature greater than 250° C.

Thus, a PCM memory having the material according to the invention as active material has a crystallisation temperature greater than 250° C. and is not subjected to the “drift” phenomenon for its LRS or SET state.

In addition to the characteristics that have just been mentioned in the preceding paragraph, the material according to the invention can have one or several additional characteristics among the following, considered individually or according to any technically permissible combinations.

According to an alternative embodiment, the ratio between the quantity of antimony Sb and the quantity of tellurium Te is comprised between 2 and 2.8, preferably between 2.3 and 2.5.

According to an alternative embodiment compatible with the preceding alternative embodiment, the ratio between the quantity of antimony Sb and the quantity of tellurium Te is substantially 2.4.

According to an alternative embodiment compatible with the preceding alternative embodiments, the material comprises between 37% and 90% germanium Ge, preferably it comprises substantially 76% germanium Ge.

According to an alternative embodiment compatible with the preceding alternative embodiments, the material comprises between 65% and 80% germanium Ge, between 15% and 25% antimony Sb and between 5% and 11% tellurium Te.

According to an alternative embodiment compatible with the preceding alternative embodiments, the material includes 76% germanium Ge, 17% antimony Sb and 7% tellurium Te.

According to an alternative embodiment compatible with the preceding alternative embodiments, the material consists of germanium Ge, tellurium Te and antimony Sb, with optionally at least one dopant.

According to an alternative embodiment compatible with the preceding alternative embodiments, the material includes at least one dopant chosen from the following group: carbon C, titanium Ti, oxygen O, phosphorus P, arsenic As, boron B, gallium Ga or silicon Si.

Thus, the crystalline growth is further slowed down.

According to an alternative embodiment compatible with the preceding alternative embodiments, the material includes at least one dopant, the dopant being nitrogen N.

Thus, the crystallisation temperature is increased and the LRS or SET state is improved. Indeed, the nitrogen N will bond to the germanium Ge and thus reduce the growth of germanium Ge aggregates in the active zone. Given that germanium Ge is a very resistive material indifferently in the LRS or HRS phase of the memory 100, preventing the formation of germanium Ge aggregates will favour the growth of the Delta material which is on the contrary responsible for the switching between the LRS or SET state and the HRS or RESET state.

According to a first alternative embodiment compatible with the preceding alternative embodiments, the material has the form of a stack of layers, with each one of the layers having a thickness less than or equal to 10 nm, preferably less than or equal to 5 nm.

According to a first embodiment of the first alternative, the stack comprises a first layer of Ge₂Sb₂Te₅, a second layer of antimony Sb and a third layer of germanium Ge doped with nitrogen N.

Thus, the materials used in the stack of layers are available by catalogue, its cost of manufacturing is therefore less.

According to an alternative embodiment of the first embodiment, the first layer has a thickness substantially of 2.5 nm, the second layer has a thickness substantially of 2.5 nm and the third layer has a thickness substantially of 10 nm.

According to a second embodiment, the stack of layers comprises a first layer of material comprising germanium Ge, antimony Sb and tellurium Te, and a second layer of germanium Ge doped with nitrogen N.

Thus, the doping with nitrogen N makes it possible to control the crystalline growth of the germanium Ge and thus increases the stability of the layers, in order to prevent a degeneration of the morphology of the stack during the melting.

According to an alternative embodiment of the second embodiment, the first layer of material comprises between 0% and 20% germanium Ge, between 50% and 70% antimony Sb and between 15% and 35% tellurium Te.

According to a second alternative embodiment compatible with the preceding alternative embodiments, the material has the form of a single layer.

A second aspect of the invention relates to a resistive phase-change memory comprising:
an upper electrode;
a lower electrode;
at least one active layer from the material according to the invention;
   the memory being intended to pass from a first resistive state to a second resistive state by application of a voltage or of a current between the upper electrode and the lower electrode.

According to an alternative embodiment, the active layer, disposed between the upper electrode and the lower electrode, has a first zone defined about an axis connecting the centre of the lower electrode and the centre of the upper electrode comprising at least one portion made from a material consisting of 10.7% germanium Ge, 62.7% antimony Sb and 26.6% tellurium Te, and a second zone located around and outside of the first zone.

A third aspect of the invention relates to a method for manufacturing the memory according to the invention, including the steps carried out in the following order:
a step of forming the lower electrode;
a step of forming the active layer of the memory;
a step of forming the upper electrode.

According to an alternative embodiment, the step of forming the active layer comprises a deposition of a single layer made from the material according to the invention or comprises the formation of a stack of layers intended to form at least partially the material according to the invention.

According to an alternative embodiment compatible with the preceding alternative embodiment, the method comprises a step of applying an electrical pulse between the upper electrode and the lower electrode, the step of applying an electrical pulse being implemented after the steps of forming the lower electrode, of forming the active layer, and of forming the upper electrode.

According to an alternative embodiment compatible with the preceding alternative embodiment, the step of forming the active layer comprises at least one substep of cathode sputtering that uses at least one sputtering target.

According to a sub-alternative embodiment of the preceding alternative embodiment, the substep of cathode sputtering uses at least one sputtering target comprised of a molecule that is chemically stable at ambient temperature, such as for example a molecule with chemical formula Ge₂Sb₂Te₅.

As the target composed of the molecule with chemical formula Ge₂Sb₂Te₅ is stable, its use makes it possible to prevent the formation of aggregates. In addition, as this target is available by catalogue, its cost is less.

According to an embodiment, the substep of cathode sputtering comprises at least one sputtering target with chemical formula Ge₂Sb₂Te₅. According to an embodiment, the substep of cathode sputtering comprises at least one sputtering target constituted of antimony Sb. According to an embodiment, the substep of cathode sputtering comprises at least one sputtering target constituted of germanium Ge. According to an embodiment, the substep of cathode sputtering is constituted by the sputtering of a target constituted of Ge₂Sb₂Te₅, of a target constituted of antimony Sb, and of a target constituted of germanium Ge.

According to a sub-alternative embodiment of the preceding alternative embodiment, the substep of cathode sputtering uses at least one sputtering target comprised of a molecule that is chemically stable at ambient temperature, such as for example a molecule comprised of 10.7% germanium Ge, 62.7% antimony Sb and 26.6% tellurium Te.

The invention and its different applications shall be understood better when reading the following description and when examining figures that accompany it.

### BRIEF DESCRIPTION OF THE FIGURES

The figures are presented for the purposes of information and in no way limit the invention.

FIG. 1 is a ternary diagram Ge—Sb—Te wherein is hatched the zone corresponding to the possible compositions for a material according to the invention.

FIG. 2 diagrammatically shows a first embodiment of a memory according to the invention.

FIG. 3 diagrammatically shows a second embodiment of a memory according to the invention.

FIG. 4 is a block diagram showing the chaining of the steps of a method for manufacturing a device according to the invention.

FIG. 5 shows the resistivity according to the temperature for an 11% germanium-enriched Delta material, for the 35% germanium-enriched Delta material, for the 49% germanium-enriched Delta material, for the 64% germanium-enriched Delta material and for the 70% germanium-enriched Delta material.

FIG. 6 shows an X-ray diffractometry of a material according to the invention comprising 35% germanium at 320° C., of the material according to the invention comprising 35% germanium at 450° C., of the material according to the invention comprising 50% germanium at 450° C., of the material according to the invention comprising 64% germanium at 450° C. and of the material according to the invention comprising 70% germanium at 450° C.

### DETAILED DESCRIPTION

Unless mentioned otherwise, the same element appearing in different figures has a unique reference.

A first aspect of the invention relates to a phase-change material able to be used as active material of a resistive phase-change memory or PCM memory for “Phase-Change Memory”.

A second aspect of the invention relates to a resistive phase-change memory having for active material the material according to the invention, i.e. including an active zone based on the material according to the invention.

The material according to the invention comprises germanium Ge, tellurium Te and antimony Sb.

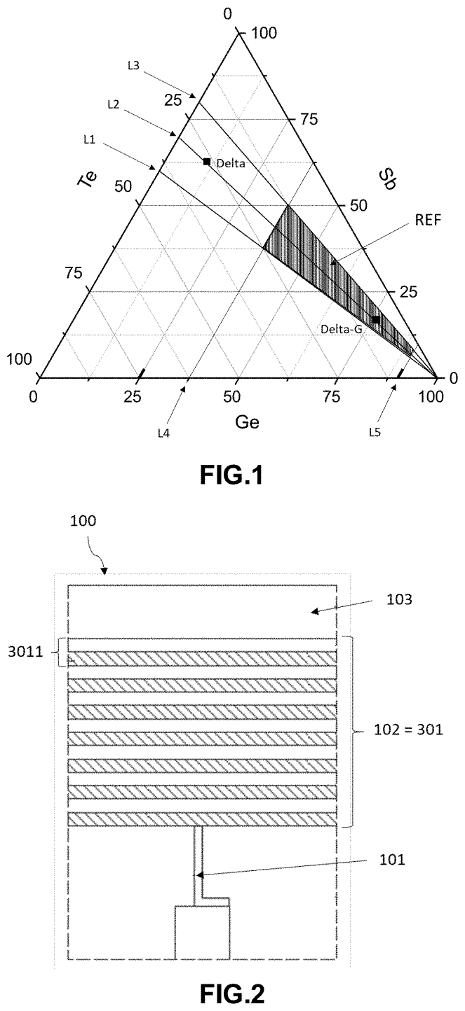

FIG. 1 is a ternary diagram Ge—Sb—Te wherein is hatched a zone REF corresponding to the possible compositions for the material according to the invention.

The percentage used all throughout the description, is a molar percentage, i.e. the term “the material comprises at least X % of an element” means that the quantity of material of the element in the material corresponds to X % of the total quantity of material of the material, whether before or after initialisation.

In the rest of the description, all the percentages used are molar percentages.

The material according to the invention comprises at least 37% germanium Ge.

When there is enough germanium Ge in the active zone of a PCM memory, the latter acts as a retardant of the nucleation and of the crystalline growth of the material of the active zone, which has for effect to increase the crystallisation temperature of the active zone.

The PCM memory according to the invention having the material according to the invention comprising at least 37% germanium Ge in its active zone therefore necessarily has a crystallisation temperature of its active zone greater than 250° C. Thus, for automotive applications, or for embedded applications, a preservation of the information stored in the PCM memory according to the invention is ensured.

The material according to the invention comprises for example between 37% and 90% germanium Ge.

In FIG. 1, the line L4 represents 37% germanium Ge, the line L5 represents 90% germanium Ge and the hatched zone REF is limited by lines L4 and L5.

Preferably, the material according to the invention comprises 76% germanium Ge.

The ratio between the quantity of antimony Sb and the quantity of tellurium Te in the material according to the invention is such that:

$$1.5 \leq \frac{Sb}{Te} \leq 4$$

In FIG. 1, the line L1 represents:

$$\frac{Sb}{Te} = 1.5$$

In FIG. 1, the line L3 represents:

$$\frac{Sb}{Te} = 4$$

According to a preferred embodiment, the ratio between the quantity of antimony Sb and the quantity of tellurium Te in the material according to the invention is such that:

$$2 \leq \frac{Sb}{Te} \leq 2.8$$

Preferably, the ratio between the quantity of antimony Sb and the quantity of tellurium Te in the material according to the invention is such that:

$$2.3 \leq \frac{Sb}{Te} \leq 2.5$$

In other words, the ratio between the quantity of antimony Sb and the quantity of tellurium Te in the material according to the invention is substantially 2.4.

The term “the ratio is substantially X” means that the ratio is X to the nearest 10%.

According to an embodiment, the ratio between the quantity of antimony Sb and the quantity of tellurium Te in the material according to the invention is strictly equal to 2.4.

In FIG. 1, the line L2 represents:

$$\frac{Sb}{Te} = 2.4$$

The material according to the invention is for example a composition comprising between 65% and 80% germanium Ge, between 15% and 25% antimony Sb and between 5% and 11% tellurium Te.

Preferably, the material according to the invention comprises 76% germanium Ge, 17% antimony Sb and 7% tellurium Te, which corresponds to the point Delta-G in FIG. 1.

According to a particular embodiment, the material according to the invention can comprise, in addition, at least one doping species.

The term “doping species or dopant of a system” means a chemical element that does not generate covalent bonds with the system, when the latter is in crystalline phase. Preferably, the proportion of dopant within the system is less than 15%, and more preferably comprised between 1% and 10% or between 1% and 5%.

The doping species is for example carbon C, titanium Ti, oxygen O, phosphorus P, arsenic As, boron B, nitrogen N, gallium Ga and/or silicon Si.

FIG. 2 diagrammatically shows a first embodiment of the memory 100 according to the invention.

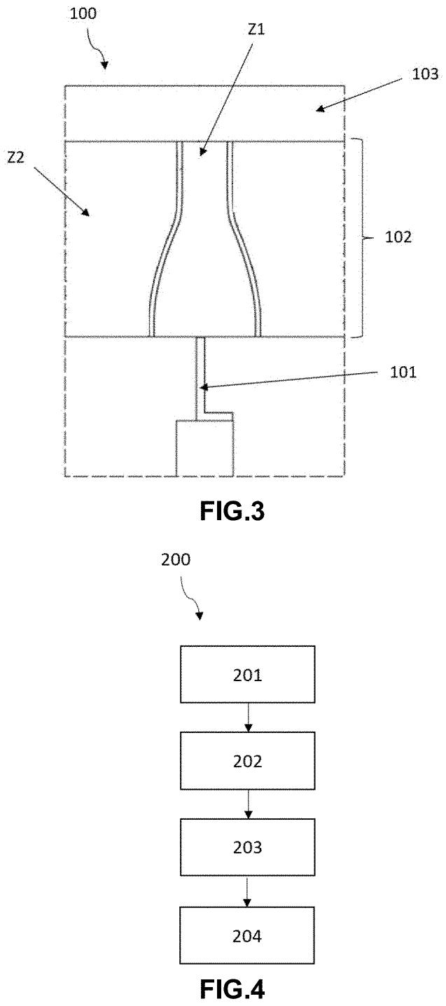

FIG. 3 diagrammatically shows a first embodiment of the memory 100 according to the invention.

Regardless of the embodiment, the memory 100 comprises:
a lower electrode 101;
at least one layer made from the material according to the invention, referred to as active layer 102; and
an upper electrode 103.

An upper electrode of a device is defined as the electrode located above this device and the lower electrode of a device as the electrode located underneath this device, the electrodes being located on either side of the device. Of course, the adjectives “upper” and “lower” are here relative to the orientation of the assembly including the upper electrode, the device and the lower electrode to the extent that when turning this assembly over, the electrode qualified hereinabove as upper becomes the lower electrode and the electrode qualified hereinabove as lower becomes the upper electrode. However, the adjectives “upper” and “lower” do not limit the invention to the disposition of the electrodes, the device able, of course to undergo a rotation of 90° in such a way as to be disposed vertically.

The lower electrode 101 and the upper electrode 103 can be planar or have the shape of an L or of an I.

In FIGS. 2 and 3, the lower electrode 101 has an L-shape and the upper electrode 103 is planar. In particular, the lower electrode 101 has an L-shape with a vertical portion that is more substantial than its horizontal portion.

The term “vertical electrode” means an electrode the maximum dimension of which is in the vertical direction.

The lower electrode 101 and upper electrode 103 are each made from a conductive material that can be different or the same for the two electrodes 101,103. Such a conductive material is for example TiN, TaN, W, TiWN, TiSiN or WN.

In the first embodiment of the memory 100, the active layer 102 comprises a stack 301 of layers, before initialisation.

Each layer of the stack 301 of layers has a thickness less than or equal to 10 nm, for example less than or equal to 5 nm.

The term “thickness of a layer” means the dimension of the layer along an axis perpendicular to a layer plane, corresponding to the plane formed by the layer. Here, the axis in question is associated with the vertical direction.

In a first alternative embodiment, the stack 301 of layers comprises for example at least two layers each made from a different material, for example a first layer of Ge₂Sb₂Te₅, a second layer of antimony Sb and a third layer of germanium Ge doped with nitrogen N.

The first layer has for example a thickness of 2.5 nm, the second layer a thickness of 2.5 nm and the third layer a thickness of 10 nm.

According to a second alternative embodiment, the stack 301 of layers comprises a first layer comprising between 0% and 20% germanium Ge, between 50% and 70% antimony Sb and between 15% and 35% tellurium Te, and a second layer of germanium Ge doped with nitrogen N.

For example, the stack 301 of layers comprises a first layer of material Delta, i.e. comprising 10.7% germanium Ge, 62.7% antimony Sb and 26.6% tellurium Te, having a thickness of 1 nm, and a second layer of germanium Ge doped with nitrogen N having a thickness of 2.7 nm.

Regardless of the alternative embodiment, the global composition of the stack 301 of layers corresponds to one of the compositions described hereinabove for the material according to the invention.

In FIG. 2, the stack 301 of layers comprises a repetition of seven substacks 3011 each comprising a first layer represented in white made from a first material and a second layer represented hatched made from a second material.

According to the second embodiment, the active layer 102 is formed by a single layer comprised of the material according to the invention.

The single layer has for example a thickness comprised between 1 nm and 100 nm, preferably a thickness greater than or equal to 10 nm.

In FIG. 2, the memory 100 according to the first embodiment is shown before initialisation, i.e. before having been subjected to a strong electrical pulse.

In FIG. 3, the memory 100 according to the second embodiment is shown after initialisation, i.e. after having been subjected to a strong electrical pulse.

During the step of initialising the memory 100 according to the invention, a reorganisation of the active zone is implemented. This reorganisation, induced under the effect of a strong electrical pulse, has for effect to create two zones within the active layer 102, a first zone Z1 defined about an axis connecting the centre of the lower electrode 101 and of the upper electrode 103 and a second zone Z2 located around and outside of the first zone Z1. The first zone Z1 and the second zone Z2 can be seen in FIG. 3.

Under the effect of the electrical initialisation pulse, a portion of the germanium Ge located in the first zone Z1 is expelled towards the second zone Z2, in such a way as to deplete the first zone Z1 of germanium Ge. However the Sb/Te ratio remains substantially identical in the first zone Z1 and the second zone Z2.

After initialisation, the first zone Z1 comprises a material called Delta, shown in FIG. 1, and germanium Ge in excess.

The Delta material is constituted of 10.7% germanium Ge, 62.7% antimony Sb and 26.6% tellurium Te. The Delta material is interesting in that it has a trigonal, even hexagonal, crystalline phase, with a very substantial crystalline growth rate ensuring strong crystalline uniformity, low resistivity, few grain boundaries and no “drift”.

The germanium Ge remaining in the first zone Z1 makes it possible to delay the nucleation and the crystalline growth of the first zone Z1, which has for effect to increase the crystallisation temperature of the first zone Z1. However, the Delta material itself, crystallises at a temperature less than 250° C.

Note that in its entirety, the material of the active layer 102 has the proportions mentioned hereinabove before and after initialisation of the memory 100.

Thus, the step of initialising induces a reorganisation of the material but does not modify the composition thereof. In the first zone Z1 and the second zone Z2, the ratio between Sb and Te remains substantially identical; only germanium Ge is mobile at the time of initialisation.

The various ratios mentioned hereinabove between Sb and Te make it possible to ensure that after initialisation, it is certain to find, in the first zone Z1, at least one portion of Delta material, which has for effect to induce a crystallinity of the first zone Z1 and at least partially in trigonal phase, more particularly in hexagonal phase, which has the advantage of having a favoured crystalline growth with respect to a cubic phase.

Following the initialisation step, the material of the invention having antimony Sb and tellurium Te in the proportions described hereinabove interacts with the germanium Ge to give rise to a nucleation allowing for a crystallisation of the active zone in a rhombohedral phase having a very substantial crystalline growth. The size and the homogeneity of such a crystalline phase makes it possible to reduce the “drift” phenomenon of the LRS or SET state.

In FIG. 3, the memory 100 is shown after initialisation, i.e. after having been subjected to a strong electrical pulse, which resulted in a reorganisation of the material, by separating it into a first zone Z1 and a second zone Z2. Note that the same separation takes place for the first embodiment. The melting of a portion of the active layer 102 therefore makes it possible to define the first zone Z1. The melting takes place about an axis connecting the centre of the lower electrode 101 and of the upper electrode 103. According to the example shown, the lower electrode 101 and the upper electrode 103 are each positioned facing one another. According to an alternative embodiment, the lower electrode 101 and the upper electrode 103 could be disposed not facing each other, but offset. In this case, the first zone Z1 would have the shape of a diagonal. In any case, the second zone Z2 is located about this central axis, outside the first zone Z1.

The doping with nitrogen N makes it possible to increase the crystallisation temperature of the active zone of the memory 100 according to the invention and to improve its LRS or SET state. Indeed, the nitrogen N will bond to the germanium Ge and thus reduce the growth of germanium Ge aggregates in the active zone. Given that germanium Ge is a very resistive material indifferently in the LRS or HRS phase of the memory 100, preventing the formation of germanium Ge aggregates will favour the growth of the phase Delta which is on the contrary responsible for the switching between the LRS or SET state and the HRS or RESET state.

A third aspect of the invention relates to a method for manufacturing the memory 100 according to the invention.

FIG. 4 is a block diagram showing the chaining of the steps of the method 200 according to the third aspect of the invention.

A first step 201 consists of forming the lower electrode 101 of the memory 100. For example, in order to obtain a planar lower electrode 101, the first step 201 consists of creating a conformal deposition of a layer of conductive material of lower electrode 101 on a substrate.

The term “conformal deposition of a layer of material on a substrate” means that the material is uniformly deposited over the entire surface of the substrate.

The substrate can comprise one or several layers: it comprises, for example, a layer with exposed copper lines that make it possible to establish metal contacts with an upper metal layer and thus comprises all of the logic required to allow the connection with the lines of the upper layers.

A second step 202 of the method 200 consists of forming the active layer 102.

In the first embodiment of the memory 100, the second step 202 consists of forming the stack 301 of layers.

In the second embodiment, the second step 202 consists of forming the single layer constituting the active layer 102.

Regardless of the embodiment, the second step 202 includes for example at least one deposition, for example a physical vapour deposition (PVD), or at least one cathode sputtering by using at least one sputtering target comprised of a molecule that is chemically stable at ambient temperature.

The second step 202 uses for example at least one sputtering target comprised of the molecule with chemical formula Ge₂Sb₂Te₅.

The second step 202 uses for example at least one sputtering target comprised of the molecule with chemical formula Ge₂Sb₂Te₅ and a sputtering target comprised of antimony Sb or of germanium Ge.

The second step 202 uses for example at least one sputtering target comprised of the Delta molecule.

Other intermediate steps can be carried out between the second step 202 and the third step 203 of the method 200, for example the formation of a selector device between the lower electrode 101 and the active layer 102 or between the active layer 102 and the upper electrode 103.

A third step 203 of the method 200 consists of forming the upper electrode 103 of the memory 100.

The third step 103 consists for example of creating a conformal deposition of a layer of conductive material of upper electrode 103, for example on the active layer 102.

The method 200 according to the invention can also comprise a fourth optional step 204 of applying an electrical pulse between the upper electrode 103 and the lower electrode 101, corresponding to the initialisation of the memory 100.

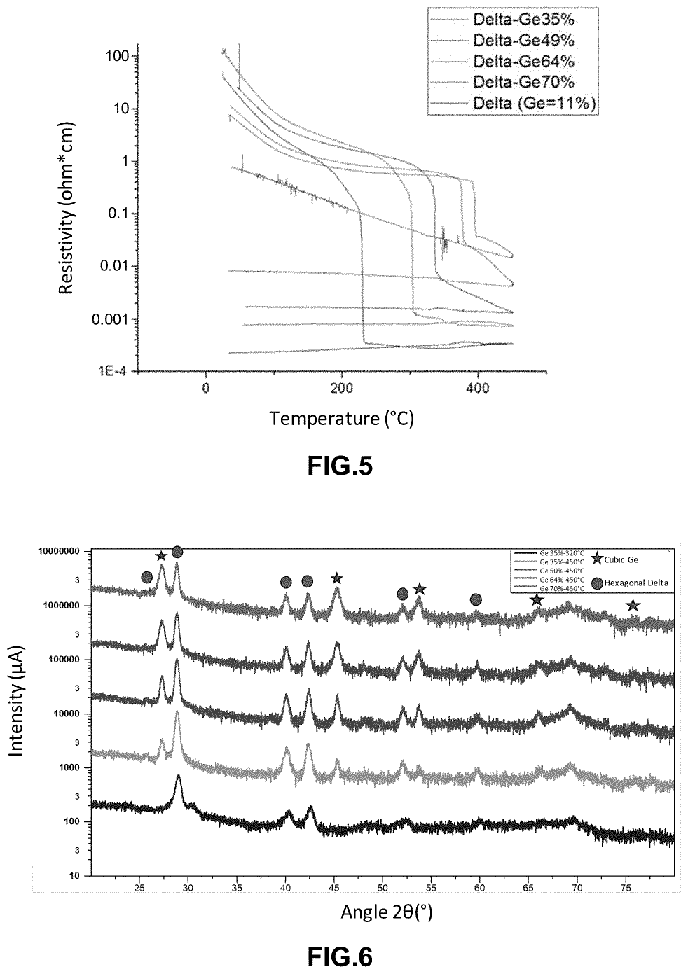

FIG. 5 shows the resistivity according to the temperature for the 11% germanium-enriched Delta material, for the 35% germanium-enriched Delta material, for the 49% germanium-enriched Delta material, for the 64% germanium-enriched Delta material and for the 70% germanium-enriched Delta material.

It is observed in FIG. 5 that the greater the quantity of germanium is, the more on the one hand, the crystallisation of the Delta material is carried out at a high temperature and the more on the other hand, the crystallisation of the Delta material is done abruptly, i.e. the more the curve becomes vertical abruptly, the abrupt nature of the crystallisation being synonymous with a very rapid crystallisation, due to the very substantial growth speed, typical of the “Delta” phase.

FIG. 6 shows an X-ray diffractometry of a material according to the invention comprising 35% germanium at 320° C., of the material according to the invention comprising 35% germanium at 450° C., of the material according to the invention comprising 50% germanium at 450° C., of the material according to the invention comprising 64% germanium at 450° C. and of the material according to the invention comprising 70% germanium at 450° C., wherein are identified the values of 28 corresponding to the cubic phase crystallised germanium and of the hexagonal phase crystallised Delta material.

It is observed in FIG. 6 that regardless of the percentage of germanium, the material each time comprises cubic phase crystallised germanium and hexagonal phase crystallised Delta material at 450°, while at 320° C., the material comprises solely hexagonal phase crystallised Delta material.

Thus, a first portion in hexagonal phase crystallised Delta material and a second portion in cubic phase crystallised germanium are indeed found at 450° C.

1. A phase-change material comprising germanium Ge, tellurium Te and antimony Sb, wherein the phase-change material comprises at least 37% germanium Ge and wherein a ratio between a quantity of antimony Sb and a quantity of tellurium Te is comprised between 2.3 and 2.5.

2. The phase-change material according to claim 1, comprising between 37% and 90% germanium Ge.

3. The phase-change material according to claim 1, comprising between 65% and 80% germanium Ge, between 15% and 25% antimony Sb and between 5% and 11% tellurium Te.

4. The phase-change material according to claim 1, consisting of germanium Ge, tellurium Te, and antimony Sb, with optionally at least one dopant.

5. The phase-change material according to claim 1, comprising at least one dopant chosen from the following group: nitrogen N, carbon C, titanium Ti, oxygen O, phosphorus P, arsenic As, boron B, gallium Ga or silicon Si.

6. The phase-change material according to claim 1, being a stack of layers, with each one of the layers having a thickness less than or equal to 10 nm.

7. The phase-change material according to claim 6, wherein the stack comprises a first layer of Ge₂Sb₂Te₅, a second layer of antimony Sb and a third layer of germanium Ge doped with nitrogen N.

8. The phase-change material according to claim 6, wherein the stack of layers comprises a first layer of material comprising germanium Ge, antimony Sb and tellurium Te, and a second layer of germanium Ge doped with nitrogen N.

9. The phase-change material according to claim 1, being a single layer.

10. A resistive phase-change memory comprising:
an upper electrode;
a lower electrode;
at least one active layer made from a phase-change material defined according to claim 1;
the memory being adapted to pass from a first resistive state to a second resistive state by application of a voltage or of a current between the upper electrode and the lower electrode.

11. The resistive phase-change memory according to claim 10, wherein the active layer, disposed between the upper electrode and the lower electrode, has a first zone defined about an axis connecting a centre of the lower electrode and a centre of the upper electrode comprising at least one portion made from a material consisting of 10.7% germanium Ge, 62.7% antimony Sb and 26.6% tellurium Te, and a second zone located around and outside of the first zone.

12. A method for manufacturing memory defined according to claim 10, comprising the steps carried out in the following order:
a step of forming the lower electrode;
a step of forming the active layer;
a step of forming the upper electrode.

13. The method according to claim 12, wherein the step of forming the active layer comprises a deposition of a single layer made from the phase-change material or comprises the formation of a stack of layers intended to form at least partially the phase-change material.

14. The method of manufacturing according to claim 12, comprising a step of applying an electrical pulse between the upper electrode and the lower electrode, the step of applying an electrical pulse being implemented after the steps of forming the lower electrode, of forming the active layer, and of forming the upper electrode.

15. The phase-change material according to claim 2, comprising substantially 76% germanium Ge.

16. The phase-change material according to claim 3, comprising 76% germanium Ge, 17% antimony Sb and 7% tellurium Te.

17. The phase-change material according to claim 6, wherein each one of the layers has a thickness less than or equal to 5 nm.
